(19) United States
(12) Patent Application Publication
(10) Pub. No.: US 2015/0129290 A1
(43) Pub. Date: May 14, 2015

(54) BASE MATERIAL FOR FORMING CONDUCTIVE PATTERN AND CONDUCTIVE PATTERN FORMED USING SAME

(71) Applicant: LG CHEM, LTD., Seoul (KR)

(72) Inventors: Jiehyun Seong, Daejeon (KR); Seung Heon Lee, Daejeon (KR); Young Chang Byun, Daejeon (KR); Jung Hyun Seo, Daejeon (KR); Jooyeon Kim, Daejeon (KR); In-Seok Hwang, Dajeon (KR); Yong Goo Son, Daejeon (KR); Beom Mo Koo, Daejeon (KR)

(21) Appl. No.: 14/383,812

(22) PCT Filed: Apr. 22, 2013
(86) PCT No.: PCT/KR2013/003393

§ 371 Date: Sep. 8, 2014

(30) Foreign Application Priority Data
Apr. 20, 2012 (KR) 10-2012-0041212

(51) Int. Cl. H05K 1/09; H05K 3/10

(52) U.S. Cl. CPC H05K 1/092; H05K 3/105; H05K 2201/0302
USPC 174/257; 427/98.4; 156/60; 156/247

(57) ABSTRACT

The present invention relates to an adhesive substrate for forming a conductive pattern, which includes an adhesive substrate, and a precursor pattern of a conductive pattern, or a conductive pattern, provided on one side of the adhesive substrate, a method for preparing a conductive pattern using the adhesive substrate, a conductive pattern prepared using the adhesive substrate, and an electronic device including the conductive pattern.

### TECHNICAL FIELD

This application claims priority from and the benefits of Korean Patent Application No. 10-2012-0041212, filed with the Korean Intellectual Property Office on Apr. 20, 2012, the entire contents of which are incorporated herein by reference.

The present invention relates to a substrate for forming a conductive pattern, a method for preparing a conductive pattern using the substrate, a conductive pattern prepared using the substrate, and an electronic device including the conductive pattern.

### BACKGROUND ART

Conductive components such as electrodes are used in electronic devices such as touch screens, displays and semiconductors. As the performance of these electronic devices increases, finer conductive patterns are required in their conductive components.

However, when a conductive pattern is directly formed on a substrate for an electronic device, which is expensive, there are problems in that the costs rise, since the high-priced substrate for the electronic device needs to be discarded when an error occurs during the formation of a conductive pattern, or when an error occurs in laminating the substrate, on which a conductive pattern is formed, with an adhesive to adhere the substrate with other components of an electronic device.

### DISCLOSURE

### Technical Problem

An object of the present invention is to provide a substrate for forming a conductive pattern, a method for preparing a conductive pattern using the substrate, a conductive pattern prepared using the substrate, and an electronic device including the conductive pattern.

### Technical Solution

A first embodiment of the present invention provides an adhesive substrate for forming a conductive pattern, which includes an adhesive substrate, and a precursor pattern of a conductive pattern provided on one side of the adhesive substrate.

In the present invention, the adhesive substrate may be an adhesive film. The constitution of the adhesive substrate can be selected depending on whether the adhesive substrate is included in an end product such as an electronic device. When the adhesive substrate is not included in an end product, it is preferable that the adhesive substrate have peel strength. Specifically, the peel strength is preferably 3,000 N or less, and more preferably 1,500 N, when an adhesive substrate specimen is prepared at a size of 2.5×12 cm², and evaluated with a 180° peel test method using a texture analyzer. When the adhesive substrate is included in an end product, the higher the adhesiveness, the better.

In the present invention, the precursor pattern of a conductive pattern means a pattern formed with materials prior to the baking of a conductive pattern, the materials exhibiting conductivity due to the baking. Herein, the precursor pattern of a conductive pattern preferably includes a material that can exhibit conductivity when baked at a low temperature, for example, a temperature of 150° C. or less. As a result, it is advantageous in forming a conductive pattern even when the adhesive substrate is formed with materials having weak heat resistance. Herein, conductivity means having specific resistance of 100 μΩ·cm or less, and specific resistance of 30 μΩ·cm or less, specific resistance of 20 μΩ·cm or less, or specific resistance of 10 μΩ·cm or less is more preferable.

A second embodiment of the present invention provides a method for preparing an adhesive substrate for forming a conductive pattern, which includes the step of forming a precursor pattern of a conductive pattern on an adhesive substrate. The step of forming the precursor pattern of the conductive pattern is not particularly limited, however, a reverse offset printing method, a Gravure offset printing method, an inkjet printing method, or the like, may be used.

A third embodiment of the present invention provides an adhesive substrate for forming a conductive pattern, which includes an adhesive substrate and a conductive pattern provided on one side of the adhesive substrate.

A fourth embodiment of the present invention provides a method for preparing an adhesive substrate for forming a conductive pattern, which includes the steps of forming a precursor pattern of a conductive pattern on an adhesive substrate, and forming a conductive pattern by baking the precursor pattern of a conductive pattern.

A fifth embodiment of the present invention provides a method for preparing a conductive pattern, which includes the steps of preparing an adhesive substrate for forming a conductive pattern including an adhesive substrate and a precursor pattern of a conductive pattern provided on one side of the adhesive substrate; laminating the surface, on which the precursor pattern is provided, of the adhesive substrate for forming a conductive pattern on an additional substrate; and forming a conductive pattern by baking the precursor pattern, either before or after laminating the additional substrate and the adhesive substrate for forming a conductive pattern.

In the method for preparing a conductive pattern, the additional substrate may be a substrate for an application in which the conductive pattern is applied last, for example, a substrate that is a component of an electronic device.

In the method for preparing a conductive pattern, it is preferable that baking is performed after lamination, since there is a concern that conductivity may be reduced when the adhesive substrate includes an adhesive ingredient that moves to the surface of the conductive pattern during the baking process.

A sixth embodiment of the present invention provides a method for preparing a conductive pattern, which includes the steps of preparing an adhesive substrate for forming a conductive pattern including an adhesive substrate and a conductive pattern provided on one side of the adhesive substrate; and laminating the surface, on which the conductive pattern is provided, of the adhesive substrate for forming a conductive pattern on an additional substrate. Herein, for the additional substrate, examples described in the embodiments described above may be applied.

The adhesive substrate may be removed after the adhesive substrate for forming a conductive pattern is laminated with the additional substrate, however, the adhesive substrate itself may be used as one component in an end application along with the conductive pattern.

The present invention provides a conductive pattern formed using the method for preparing a conductive pattern described above.

In addition, the present invention provides an electronic device that includes the conductive pattern described above.

### Advantageous Effects

When an adhesive substrate for forming a conductive pattern according to the present invention is used, the costs can be reduced since, when an error occurs during the conductive pattern formation, the adhesive substrate is less expensive than components such as glass or plastic substrates used in an end application such as an electronic device.

In addition, the adhesive substrate, by being used in the form of being adhered to other components as a component of an end application, may prevent the disuse of a high-price component due to an error occurring when a component, in which a conductive pattern is formed, is laminated with an adhesive to be adhered to other components of an electronic device, as in the related art.

Furthermore, even when a substrate on which it is difficult to directly form a conductive pattern in an end application is used, for example, when the polarity or surface energy of the substrate is incompatible with the composition for forming a conductive pattern, when a substrate is not planar and has a curved surface, or when it is difficult to directly form a conductive pattern on the substrate due to surface characteristics such as the roughness of the substrate surface, a conductive pattern can be readily formed according to the present invention.

In addition, in the present invention, when a composition that does not include a polymer binder or a composition that includes minimum amounts of a polymer binder is used as the material for forming the conductive pattern, the conductive pattern is suitable for a printing method, particularly a roll printing method and a reverse offset printing method, it is possible to obtain a conductive pattern having excellent conductivity and a fine conductive pattern, the conductive pattern has excellent adhesion with a substrate, and it is possible to realize conductivity via low-temperature baking.

### DESCRIPTION OF DRAWINGS

FIG. 1 illustrates an adhesive substrate for forming a conductive pattern according to one embodiment of the present invention.

FIG. 2 illustrates a process schematic view of a reverse offset printing method.

FIG. 3 shows a photograph of the conductive pattern obtained in Example 1.

FIG. 4 shows a bezel electrode-forming process schematic view of a touch screen according to the related art.

Each of FIG. 5 to FIG. 12 shows a bezel electrode-forming process schematic view of a touch screen according to embodiments of the present invention.

### MODE FOR DISCLOSURE

Hereinafter, the present invention will be described in more detail.

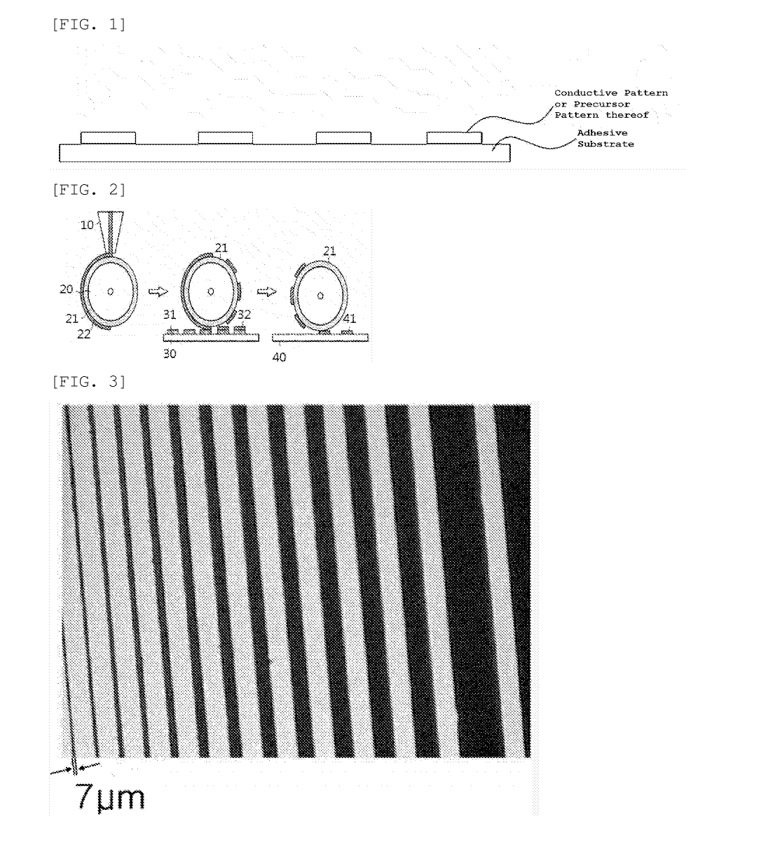

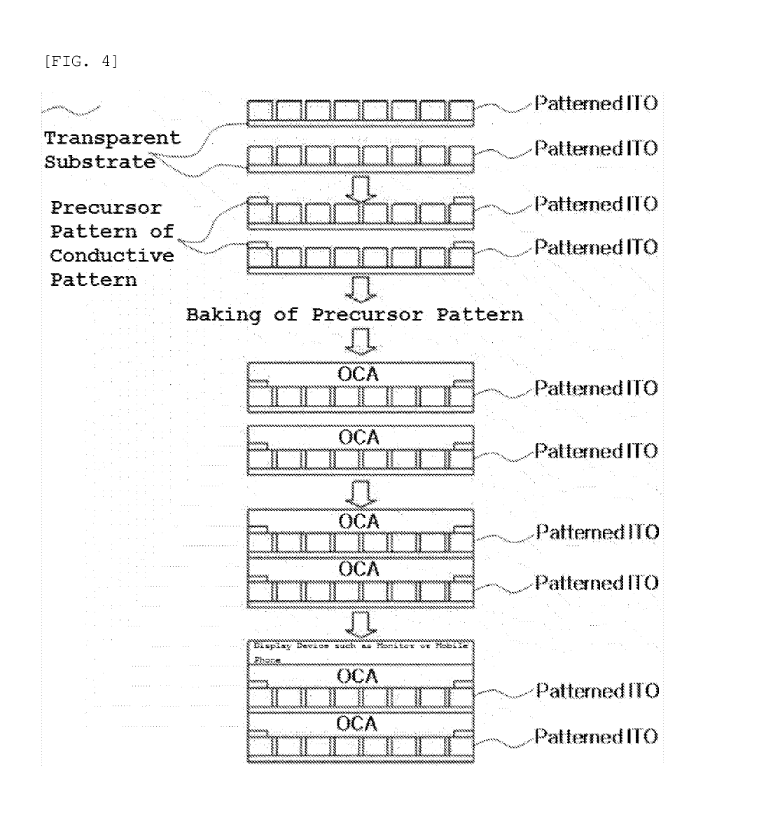

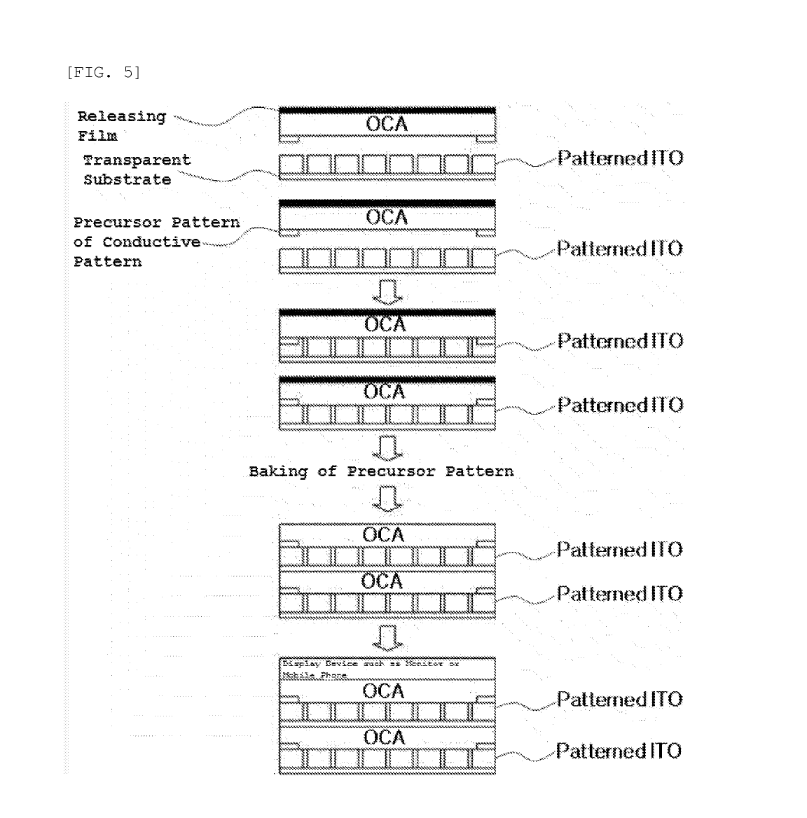

One embodiment of the present invention provides an adhesive substrate for forming a conductive pattern, which includes an adhesive substrate, and a precursor pattern of a conductive pattern, or a conductive pattern, provided on one side of the adhesive substrate. In FIG. 1, one example of an adhesive substrate for forming a conductive pattern according to the present invention is shown in the diagram. The adhesive substrate for forming a conductive pattern according to FIG. 1 has a structure in which a precursor pattern of a conductive pattern, or a conductive pattern, is provided on an adhesive substrate. The pattern shape of the precursor pattern of a conductive pattern, or the conductive pattern, shown by the diagram in FIG. 1, is for illustrative purposes only, and the scope of the present invention is not limited thereto. The shape of the pattern may be designed to have the shape required by the end application.

In the present invention, the adhesive substrate may be an adhesive film.

In the present invention, when the adhesive substrate is present without being removed in an end application in which the conductive pattern is used, the adhesive substrate is preferably transparent in the visible region. For example, when the adhesive film remains as a component of an end application along with the conductive pattern without being removed, the adhesive film is preferably transparent. In the present specification, being transparent means that light transmittance is 60% or more, preferably 75% or more, more preferably 90% or more, and even more preferably 95% or more.

It is preferable that a releasing film be provided on the opposite side of the surface of the adhesive substrate on which a pattern for forming a conductive pattern is provided.

It is preferable that the precursor pattern of a conductive pattern be prepared using a composition that does not include a polymer binder, or that includes minimum amounts thereof. Accordingly, it is preferable that the prepared conductive pattern also do not include a polymer binder, or that it include minimum amounts thereof. If a polymer binder remains when the baking temperature is low, it causes a reduction in conductivity. In addition, the ingredients of the adhesive substrate are often mixed with the polymer binder, and it may cause problems when the adhesive substrate needs to be peeled off afterwards.

The precursor pattern of a conductive pattern may be formed as a composition for forming a conductive pattern, which includes conductive particles and a solvent. The solvent preferably include a first solvent having a vapor pressure of 3 torr or less at 25° C. and a second solvent having a vapor pressure of greater than 3 torr at 25° C.

The composition for forming a conductive pattern may further include a surfactant as necessary. In addition, the composition for forming a conductive pattern may further include an organic metal. Accordingly, a surfactant or an organic metal may be included within the precursor pattern of a conductive pattern, or the conductive pattern. In other words, the precursor pattern of a conductive pattern may further include at least one of a surfactant and an organic metal.

The composition for forming a conductive pattern preferably does not include a polymer binder or a releasing agent, or includes minimum amounts thereof. The size of the conductive particles is not particularly limited, as long as, after the baking, conductivity can be obtained within a desired range and a fine pattern can be obtained as desired. However, when the adhesive substrate is removed after laminating the adhesive substrate provided with the precursor pattern of a conductive pattern, or the conductive pattern, on an additional substrate, it is preferable that the conductive particles not be too small. When the conductive particles are too small, adhesion with the additional substrate is strong, but adhesion with the adhesive substrate is also strong, and therefore it is difficult to remove the adhesive substrate even when the adhesive substrate needs to be removed last. According to one embodiment, the particle size of the conductive particles may be 2 micrometers or less. According to other embodiments, the particle size of the conductive particles may be 1 micrometer or less, may range from 5 to 500 nm, or may range from 40 to 400 nm.

In one specific embodiment, the composition for forming a conductive pattern may include metal particles, a first solvent having a vapor pressure of 3 torr or less at 25° C. and a second solvent having a vapor pressure of greater than 3 torr at 25° C., and a salt of metal carboxylic acid. The composition for forming a conductive pattern may not substantially include a polymer binder or a releasing agent.

The composition for forming a conductive pattern is suitable for a printing method, particularly a roll printing method, and most particularly a reverse offset printing method using a printing blanket of a rubber material, for the reasons described below.

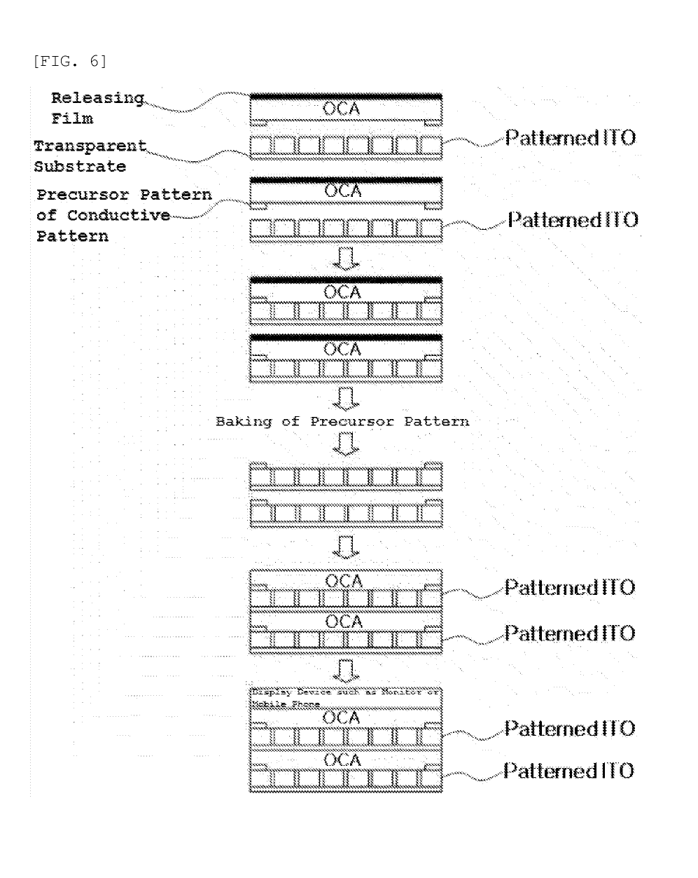

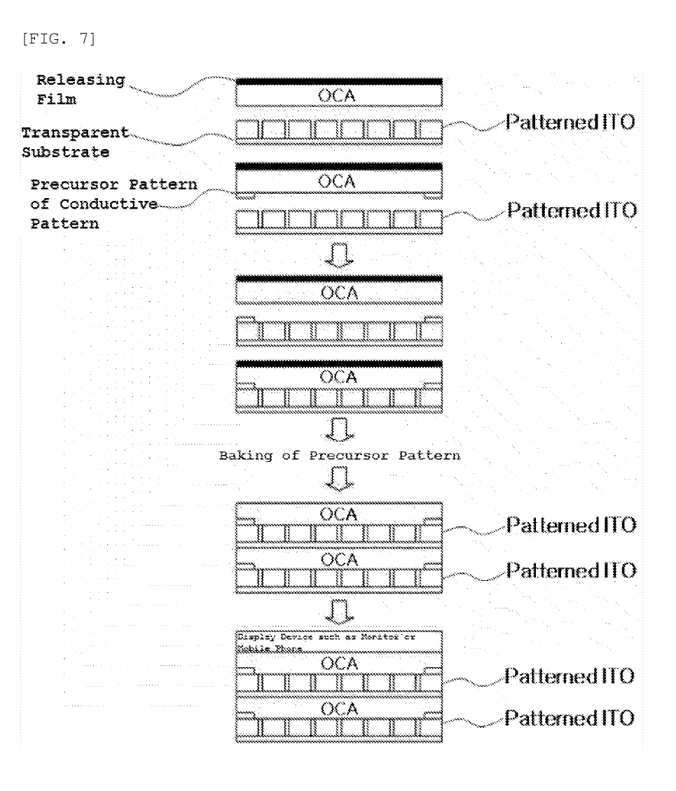

For reference, a reverse offset printing method includes the steps of i) applying a composition for forming a conductive pattern on a roller; ii) forming a pattern of a composition for forming a conductive pattern that corresponds to the conductive pattern on the roller by contacting a cliche, on which a pattern that corresponds to the conductive pattern to be formed is formed by engraving, with the roller; and iii) transferring the pattern of the composition for forming a conductive pattern, which is on the roller, on a substrate. At this time, the perimeter of a roller is composed of a printing blanket of a rubber material having elasticity. This kind of reverse offset printing method is illustrated in FIG. 2.

In a common composition for forming a conductive pattern, a polymer binder is added so that, after coating on a roller, a uniform film can be formed without cracks or pinholes. However, when a polymer binder is added, specific resistance becomes excessively high when baking is performed at a low temperature of 200° C. or less, therefore, it may be difficult to use a polymer binder in the fields in which excellent conductivity is required when baking is performed at a low temperature.

Meanwhile, if a polymer binder is not included, cracks or pinholes may occur in the film after printing, or problems such as poor transfer or poor straightness of the pattern may occur. At this time, if a salt of metal carboxylic acid is added to the composition for forming a conductive pattern, the salt of metal carboxylic acid may play the following role. First, the salt of metal carboxylic acid may contribute to the conductivity improvement by being reduced to a metal in the baking process. Second, the salt of metal carboxylic acid can improve the coating properties of the composition for forming a conductive pattern, and can improve the transference and straightness of the pattern by replacing the polymer binder of the composition for forming a conductive pattern.

In the composition for forming a conductive pattern, ingredients other than the metal particles, the salt of metal carboxylic acid and a surfactant, which is added when necessary, preferably have a weight average molecular weight of less than 800. In addition, in the composition for forming a conductive pattern, ingredients other than the metal particles and the salt of metal carboxylic acid are preferably liquids.

The salt of metal carboxylic acid is not particularly limited by the chain length of an alkyl group, the presence of a branch, the presence of a substrate, and the like, as long as it is soluble in a suitable organic solvent.

The amount of the salt of metal carboxylic acid used is preferably 0.1 to 20 parts by weight with respect to the content of metal particles, which is 100 parts by weight. When the salt of metal carboxylic acid is included in an amount of less than 0.1 parts by weight with respect to the content of metal particles, which is 100 parts by weight, the contribution of the salt of metal carboxylic acid to the improvement of pattern straightness and to the improvement of conductivity is insignificant. Furthermore, when the content of the salt of metal carboxylic acid is 20 parts by weight or less with respect to the content of metal particles, which is 100 parts by weight, it is advantageous to uniformly mix the metal particles and the salt of metal carboxylic acid, by which a stable and uniform coated film is readily formed after the printing.

The metal of the salt of metal carboxylic acid may be the same as or different from the metal types of the metal particles, however, it is preferable to use the same types. In addition, silver is most preferable in consideration of conductivity. The carbon number of the salt of metal carboxylic acid preferably ranges from 2 to 10.

The composition for forming a conductive pattern preferably includes two or more solvents as well. As a first solvent, a solvent having relatively low volatility, that is, a solvent of which the vapor pressure is 3 torr or less at 25° C. may be used. The first solvent may be used as a medium for dispersing a composition for forming a conductive pattern until printing and baking. As a second solvent, a solvent having relatively high volatility, that is, a solvent of which the vapor pressure is greater than 3 torr at 25° C. may be used. The second solvent, together with the first solvent, may ensure that the composition for forming a conductive pattern maintains a low viscosity and excellent roller coating properties until the composition for forming a conductive pattern is applied on a substrate or a roller. Furthermore, the second solvent is an ingredient that is removed by volatilization after being applied on a substrate or a roller, and thereby can raise the viscosity of the composition for forming a conductive pattern and can make the pattern be well formed and preserved on the substrate and the roller.

The amount of the first solvent and the second solvent used may be determined considering the use, the working environment, and the like. It is preferable that the amount of the second solvent, which is a highly volatile solvent, be raised in order to quickly form the coated film of a composition for forming a conductive pattern, and thereby reduce the tact time of a whole process, and it is preferable that the amount of the second solvent be reduced in order to secure room in the process by slowing down the formation of the coated film of a composition for forming a conductive pattern. Preferably, with respect to the total amount of the solvent used, the amount used may be adjusted to be within the range of 0.1 to 60% by weight for the first solvent, and 1 to 80% by weight for the second solvent.

Examples of the low-volatile solvent that can be used as the first solvent include dimethylacetamide, gamma butyrolactone, hydroxytoluene, propylene glycol monobutyl ether, propylene glycol monopropyl ether, butyl cellosolve, glycerine, phenoxyethanol, butyl carbitol, methoxy propoxy propanol, carbitol, terpineol, triethylene glycol monoethyl ether, triethylene glycol monomethyl ether, N-methylpyrrolidone, propylene carbonate, dimethylsulfoxide, diethylene glycol, triethanolamine, diethanolamine, triethylene glycol, ethylene glycol, or the like, and two or more of these can be mixed and used. However, the first solvent is not limited to the above examples.

Examples of the second solvent having high volatility include dimethyl glycol, methanol, ethanol, isopropanol, propanol, hexane, heptane, octane, 1-chlorobutane, methylethylketone, cyclohexane, or the like, and two or more of these can be mixed and used. However, the second solvent is not limited to the above examples.

In addition, the second solvent having high volatility preferably has surface tension of less than 26 dyn/cm so that the second solvent has excellent roller coating properties in Step i) of FIG. 2. In addition, a considerable portion of the second solvent is removed by volatilization prior to Step ii) of FIG. 2, therefore, the first solvent, having low volatility, is mainly left in Step ii) and Step iii). In the above Step ii) and Step iii), the surface tension of the first solvent is preferably 26 dyn/cm or more in order to increase the release strength of the composition for forming a conductive pattern.

Meanwhile, the solvent is preferably a polar solvent. Generally, the polarity of a solvent increases as the solubility constant of the solvent increases, therefore, it is preferable that the solubility constant of the solvent be high.

The solvent may include a solvent having a solubility constant of 10 (cal/cm³)^{1/2} or more when presented in an amount of 80% by weight or more based on the total weight of the solvent. As a result, contamination of a roller by the composition for forming a conductive pattern can be minimized.

In order to minimize the contamination of a roller due to ink ingredients, absorption of the ink ingredients into the printing blanket made of an elastic rubber material, which is the main ingredient of the perimeter of a roller, needs to be minimized. For this, the solubility constant of the solvent in the ink is preferably 10 (cal/cm)^{1/2} or more, since the ink ingredients would not be absorbed into the printing blanket when the difference between the solubility constant of the solvent in the ink and the solubility constant of the printing blanket of an elastic rubber material is bigger. It is preferable that, as in the present invention, the average value of the solubility constant be 10 (cal/cm³)^{1/2} or more based on the weight composition of the solvent when two or more types of solvents are mixed.

Metal particles giving conductivity within the composition for forming a conductive pattern preferably have a nanoscale average particle size in order to obtain a fine pattern. For example, in order to obtain a hyperfine pattern having a line width of less than 6 micrometers and a line spacing of less than 3 micrometers, it is preferable to have a nanoscale average particle size, and more preferably, to have an average particle size ranging from 5 to 400 nanometers.

As the metal particle, those having high conductivity are preferable, for example, metal particles having specific resistance of 20 μΩ·cm or less, specific resistance of 10 μΩ·cm or less, or specific resistance of 3 μΩ·cm or less may be used. As specific examples, the metal particle is preferably a silver or a copper particle in terms of high conductivity. The specific resistance of bulk silver is 1.59 μΩ·cm, the lowest among metals, and the specific resistance is just 65% compared to copper, which has the second low specific resistance. Therefore, when a composition for forming a conductive pattern is prepared by granulating silver and is printed in order to form an electrode, obtaining desired conductivity after baking is relatively easy when silver is used compared to other metals, even when there are many other additives in addition to silver particles. It is particularly preferable to use silver particles as metal particles in order to prepare a composition for forming a conductive pattern for the reasons that silver has lower specific resistance than copper, and that conductivity can be obtained without the silver particles being oxidized even when a separate inert gas atmosphere and reduction atmosphere are not created.

The amount of the metal particles used is not particularly limited, but preferably ranges from 10% by weight to 50% by weight based on the total weight of a composition for forming a conductive pattern. If the amount of the metal particles is 50% by weight or less, it is easier to adjust the initial viscosity of a composition for forming a conductive pattern to 20 cps or less, and prevent an increase in the price of the composition for forming a conductive pattern. If the amount of the metal particles used is 10% by weight or more, it is efficient in obtaining conductivity within the composition for forming a conductive pattern. The initial viscosity of the composition for forming a conductive pattern can be adjusted to 1 cps or more.

Furthermore, when a polymer binder is used, as in common compositions for forming a conductive pattern, it is possible to form a uniform film after a composition for forming a conductive pattern is coated on a roller by using a suitable polymer binder even when the amount of the metal particles is less than 10% by weight. However, as in the embodiments described above, when a polymer binder ingredient is not separately added, using the metal particles in an amount of 10% by weight or more is advantageous in the coated composition for forming a conductive pattern because a uniform film can be formed without defects such as pinholes or cracks.

The composition for forming a conductive pattern described above does not use a polymer binder, but uses a salt of metal carboxylic acid instead, so that excellent conductivity can be exhibited even when baked at a low temperature. When a salt of metal carboxylic acid and metal particles are used together, advantages are conveyed in that conductivity is improved as the salt of metal carboxylic acid is reduced to a metal in the baking process and in that the gap between the metal particles is filled.

The initial viscosity of the composition for forming a conductive pattern is preferably 20 cps or less, and more preferably 10 cps or less. If the initial viscosity is in the above range, it is also advantageous in the aspect of coating properties.

The initial surface energy of the composition for forming a conductive pattern is preferably 24 dyn/cm or less, and more preferably 21.1 to 23.9 dyn/cm. If the initial surface energy is in the above range, it is advantageous in the aspect of coating properties.

The composition for forming a conductive pattern may additionally include a surfactant. Common leveling agents, for example, silicon-based, fluorine-based or polyether-based surfactants, may be used as the surfactant. The content of the surfactant is preferably 0.01 to 5% by weight based on the total weight of the composition for forming a conductive pattern.

The composition for forming a conductive pattern may be prepared by mixing the ingredients described above and filtering the result using a filter when necessary.

By applying a roll printing process, particularly a reverse offset process using the composition for forming a conductive pattern, a finer conductive pattern can be favorably formed on a substrate. In particular, when the composition for forming a conductive pattern is applied to a reverse offset process, a fine conductive pattern that was not able to be formed using an inkjet printing method and the like, which used to be previously applied, for example, a conductive pattern having a line width and a line spacing of a few micrometers to tens of micrometers, specifically, approximately 3 to 80 μm or approximately 3 to 40 μm, can be favorably formed. In particular, by using the composition for forming a conductive pattern and a roll printing process, even a fine conductive pattern having a line width of approximately 3 to 10 μm and a line spacing of approximately 3 to 10 μm can be favorably formed.

When a composition that does not include the polymer binder described above is used, a conductive pattern having excellent conductivity can be formed even when baked at a relatively low temperature, such as 200° C. or less, 110° C. to 200° C., or 130° C. to 200° C. As a result, by applying the composition for forming a conductive pattern and the method of forming the conductive pattern described above, a fine conductive pattern having excellent conductivity even at a low temperature can be provided. Since low-temperature baking can be applied, the precursor pattern of a conductive pattern, or the conductive pattern, can be formed on the adhesive substrate, which can significantly contribute to improving the visibility of flexible display devices and flat display devices, making flexible display devices and flat display devices that have a large area, or the like.

When a precursor pattern of a conductive pattern formed using the composition for forming a conductive pattern is baked, the time of baking can be determined depending on the ingredients and the composition, for example, the baking can be performed for 3 minutes to 60 minutes.

Another embodiment of the present invention provides a method for preparing an adhesive substrate for forming a conductive pattern, which includes the step of forming a precursor pattern of a conductive pattern on an adhesive substrate. A reverse offset printing method, a Gravure offset printing method, an inkjet printing method, or the like, may be used in the step of forming the precursor pattern of a conductive pattern.

Another embodiment of the present invention provides an adhesive substrate for forming a conductive pattern, which includes an adhesive substrate and a conductive pattern provided on one side of the adhesive substrate. This adhesive substrate for forming a conductive pattern may be prepared using a method that includes the steps of forming a precursor pattern of a conductive pattern on an adhesive substrate and forming a conductive pattern by baking the precursor pattern of a conductive pattern. In this embodiment, the description according to the embodiments described above may be applied, except that a conductive pattern is provided instead of a precursor pattern of a conductive pattern on an adhesive substrate.

As the baking, various methods such as heat baking, microwave oven baking, IR baking and laser baking may be applied. Heat baking may be performed, for example, for 3 minutes to 60 minutes at 150° C. or less, or in the range from 110 to 150° C.

Another embodiment of the present invention provides a method for preparing a conductive pattern, which includes the steps of preparing an adhesive substrate for forming a conductive pattern including an adhesive substrate and a precursor pattern of a conductive pattern provided on one side of the adhesive substrate; laminating the surface, on which the precursor pattern is provided, of the adhesive substrate for forming a conductive pattern on an additional substrate; and forming a conductive pattern by baking the precursor pattern, either before or after laminating the additional substrate and the adhesive substrate for forming a conductive pattern.

In the method for preparing a conductive pattern, the type of the additional substrate is not particularly limited, and may be determined depending on the end use in which the conductive pattern is applied, and for example, it may be a substrate that is a component of an electronic device. The additional substrate may be a glass or a plastic substrate, or may be a plastic film. In the present invention, a conductive pattern can be readily formed even on substrates on which it was previously not possible to form a conductive pattern, by first forming a precursor pattern of a conductive pattern, or a conductive pattern, on an adhesive substrate.

In the additional substrate, additional constituents that are required in an end application may be provided. For example, in the additional substrate, a conductive pattern, specifically, a transparent conductive oxide pattern or a metal pattern, may be provided. In this case, the adhesive substrate may be laminated so that the surface of the adhesive substrate, on which a precursor pattern of a conductive pattern or a conductive pattern is provided, adjoins the surface of the additional substrate on which a conductive pattern is provided.

In the method for preparing a conductive pattern, if there is a concern that, in the baking process, the adhesive ingredient may move above the conductive pattern depending on the ingredients of the adhesive substrate, baking is preferably performed after lamination in order to prevent the reduction of conductivity.

Another embodiment of the present invention provides a method for preparing a conductive pattern, which includes the steps of preparing an adhesive substrate for forming a conductive pattern including an adhesive substrate and a conductive pattern provided on one side of the adhesive substrate; and laminating the surface, on which the conductive pattern is provided, of the adhesive substrate for forming a conductive pattern on an additional substrate. Herein, for the additional substrate, examples described in the embodiments described above may be applied.

The adhesive substrate in the adhesive substrate for forming a conductive pattern may be removed after the adhesive substrate for forming a conductive pattern is laminated with the additional substrate and a conductive pattern is formed, however, the adhesive substrate itself may be used as one component in an end application along with the conductive pattern. For example, the adhesive substrate may be used to adhere to other components in an end application. However, if the adhesive substrate is not suitable for an end application, the adhesive substrate may be removed. For example, if the adhesive substrate is not suitable for an end application in the aspect of adhesiveness or permittivity, it may be replaced with other adhesive layers or other films that satisfy such purposes. When the adhesive substrate included in the adhesive substrate for forming a conductive pattern remains without being removed from an end product, the adhesive substrate is preferably transparent in the visible region. In this case, it is advantageous when the conductive pattern prepared according to the method of the present invention is used for displays, and the like.

The present invention provides a conductive pattern formed using the method for preparing a conductive pattern described above.

According to the present invention, by using the composition for forming a conductive pattern described above, the conductive pattern may have low specific resistance of less than 25 μΩ·cm even when being baked at a low temperature of 200° C. or less. In addition, the conductive pattern may have excellent adhesiveness with a substrate, and may have a line width and line spacing of 3 to 80 μm, approximately 3 to 40 μm, or approximately 3 to 10 μm. Furthermore, due to low specific resistance, the line height is not unnecessarily raised, therefore, the visibility of the device is improved, and it is advantageous in making the device in the form of a thin film. The line height that can be used depends on the printing line width and the line spacing, however, desired conductivity can be obtained even with line width and the line spacing of less than 1 μm. In the present invention, the line height may be adjusted to 100 nm or more as necessary.

For example, according to the present invention, the conductive pattern may have specific resistance of 100 μΩ·cm or less, 30 μΩ·cm or less, 20 μΩ·cm or less, or 10 μΩ·cm or less. The conductive pattern according to the present invention may have an aperture ratio of 90% or more, and a transparent conductive film having sheet resistance of 100Ω/□ or less, 50Ω/□ or less, or 10Ω/□ or less can be provided even when the line height thereof is less than 1 μm, 500 nm or less, or 200 nm or less.

As specific examples, there is a transparent conductive film that can be applied in touch screens and the like, as one of the application examples that can be achieved using the composition for forming a conductive pattern. In the case of an ITO/PET film, an existing transparent conductive film that has been used for touch screens, sheet resistance ranges from 50 to 300Ω/□. However, when the composition for forming a conductive pattern provided in Example 1 according to one embodiment of the present invention described below is printed on a substrate and baked for 30 minutes at 150° C., since the specific resistance is 20 μΩ·cm or less, a transparent conductive film, the sheet resistance of which is approximately 10Ω/□ or less while the transmittance thereof is simultaneously increased, can be produced by using a pattern having an aperture of 90% or more, even with a film thickness of less than 200 nm. Therefore, the preparation of a transparent conductive film having higher conductivity than transparent conductive films in which the whole surface is coated is possible, which is advantageous in making touch screen panels having a large area.

As another specific example, one of the application examples that can be achieved using the composition for forming a conductive pattern includes a bezel electrode of a touch screen, an electrode pattern for touch sensing, or includes both. When the adhesive substrate provided with the precursor pattern of a conductive pattern, or provided with the conductive pattern, is used in preparing a bezel electrode of a touch screen, the adhesive substrate, on which the precursor pattern of a conductive pattern, or the conductive pattern is formed, may be laminated on an additional substrate provided with a transparent conductive oxide pattern, for example, an ITO pattern or a metal pattern. Herein, a pattern known in the related art may be used as the transparent conductive oxide pattern or the metal pattern.

The shape of the conductive pattern may be determined depending on the end application. The conductive pattern may be a regular pattern such as a mesh pattern, or an irregular pattern.

In addition, the present invention provides an electronic device that includes the conductive pattern described above. The type of the electronic device is not particularly limited, and includes touch screens, displays, and the like.

Hereinafter, examples in which the present invention is applied to the formation of a bezel electrode of a touch screen will be described with reference to drawings, however, the description below is for illustrative purposes only, and is not intended to limit the scope of the present invention.

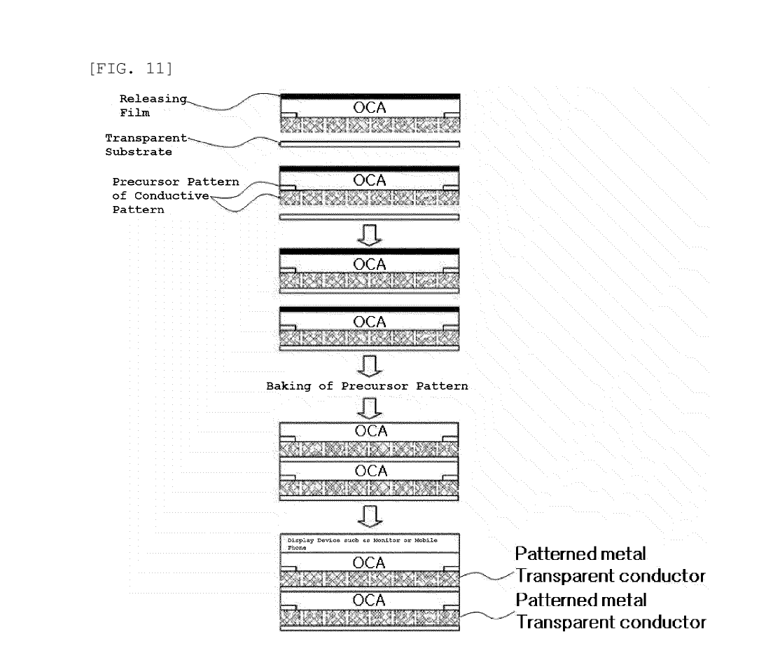

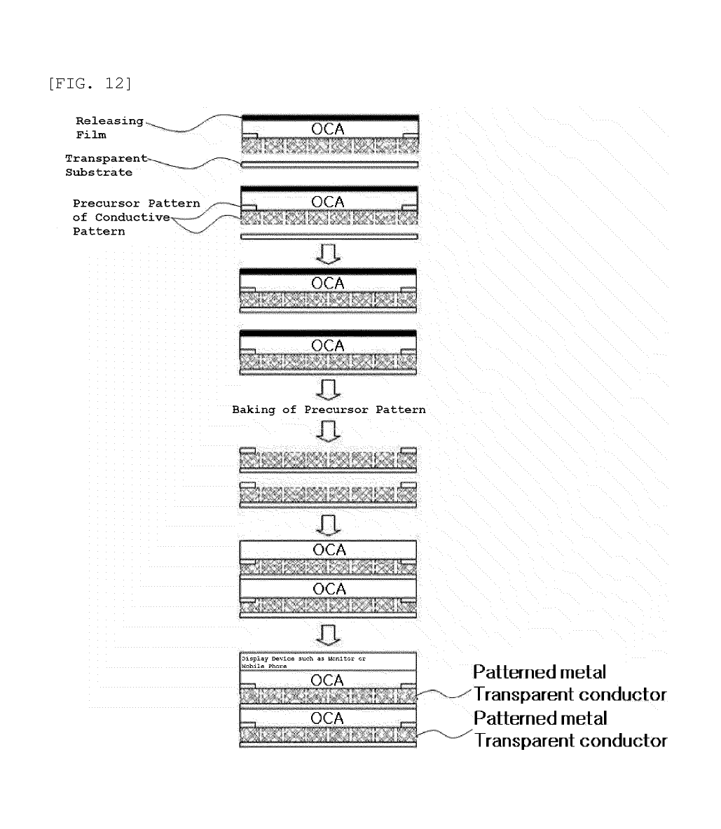

FIG. 4 shows a bezel electrode-forming process schematic view of a touch screen according to the related art. According to FIG. 4, a bezel electrode is formed on an ITO electrode of a transparent substrate that is provided with the ITO electrode, and the bezel electrode is adhered with other components using an optical clear adhesive (OCA) substrate.

FIG. 5 to FIG. 12 show a bezel electrode-forming process schematic view of a touch screen according to embodiments of the present invention.

According to FIG. 5, after a transparent substrate provided with an ITO electrode and an optical clear adhesive (OCA) substrate provided with a precursor pattern of a bezel electrode are laminated, the precursor pattern is baked, and then components are adhered using the optical clear adhesive substrate.

FIG. 6 is the same as FIG. 5 except that, after the baking of the optical clear adhesive precursor pattern, the optical clear adhesive substrate that was used to form the precursor pattern of a bezel electrode is removed, and a new optical clear adhesive substrate is laminated.

In FIG. 7, an example is shown by the diagram in which one of the two electrode structures forms a bezel electrode according to the present invention as in FIG. 5, and the other forms a bezel electrode according to the related art, as in FIG. 4.

FIG. 8 is the same as FIG. 7 except that, after the baking of a precursor pattern, the optical clear adhesive substrate that was used to form the precursor pattern of a bezel electrode is removed, and a new optical clear adhesive substrate is laminated.

FIG. 9 and FIG. 10 are the same as FIG. 5 and FIG. 6, respectively, except that the electrode provided on the transparent substrate is a transparent conductive metal electrode instead of an ITO electrode. Herein, the transparent conductive metal electrode may be formed with a metal pattern.

According to FIG. 11, a precursor pattern of a bezel electrode and a precursor pattern of a transparent conductive metal electrode for touch sensing are formed on an optical clear adhesive substrate, and after laminating this with a transparent substrate, the precursor pattern is baked, and the components are adhered using the optical clear adhesive substrate.

FIG. 12 is the same as FIG. 11 except that the optical clear substrate that formed a precursor pattern is removed after the baking of the precursor pattern, and a new optical clear adhesive substrate is laminated.

In FIG. 8 to FIG. 12, only the areas in which a metal pattern is formed are shown, and the shape of the metal pattern is not specifically shown by the diagram, however, those skilled in the art can design pattern shapes and sizes, for example, line widths, line spacing and the like, known in the related art, depending on the purpose of the end application.

Hereinafter, the present invention will be described in more detail with reference to examples. However, the examples are for illustrative purposes only, and are not intended to limit the scope of the present invention.

### Example 1

A composition for forming a conductive pattern was prepared by mixing 30 g of silver nanoparticles having an average particle size of 120 nm, 1.7 g of a silver salt of neodecanoic acid (Ag-neodecanoate), 0.6 g of a surfactant, 4 g of terpineol (vapor pressure of 0.042 torr; surface tension of 33.2 mN/m; solubility constant of 9.80 (cal/cm³)^{1/2} at 25° C.) and 36 g of propyl cellosolve (vapor pressure of 0.98 torr; surface tension of 26.3 mN/m; solubility constant of 10.87 (cal/cm³)^{1/2} at 25° C.) as a first solvent, and 33 g of ethanol (vapor pressure of 59.3 torr; surface tension of 22.1 mN/m; solubility constant of 12.98 (cal/cm³)^{1/2} at 25° C.) as a second solvent, and by filtering the result using a 1 micrometer filter after stirring for 24 hours.

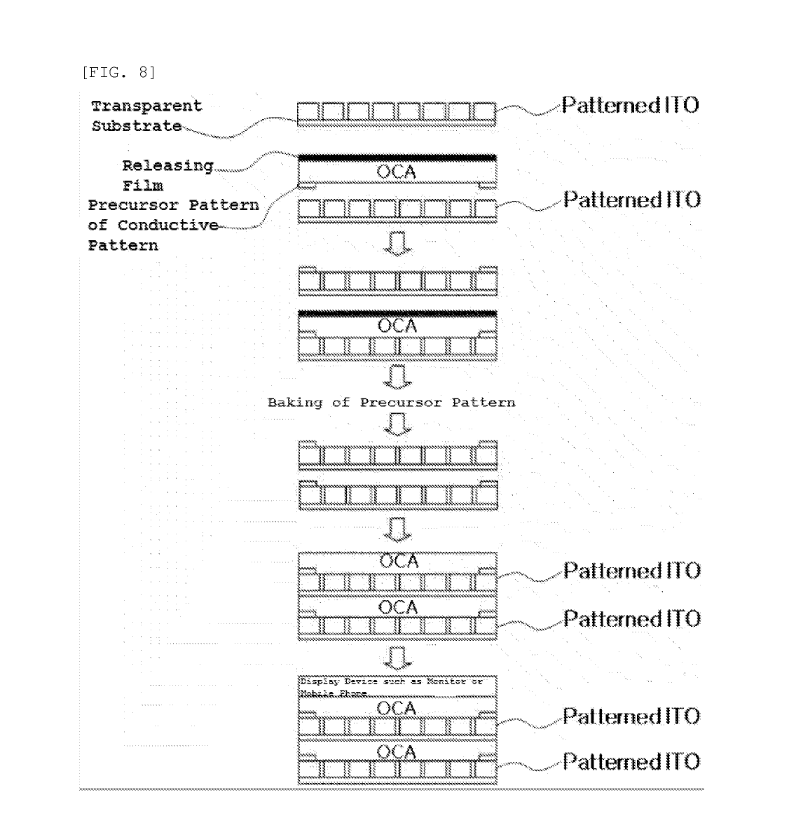

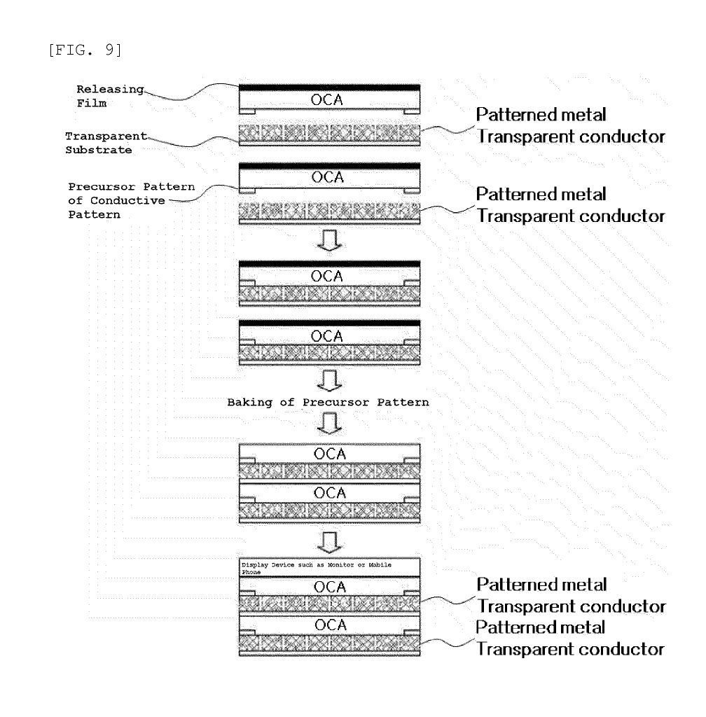

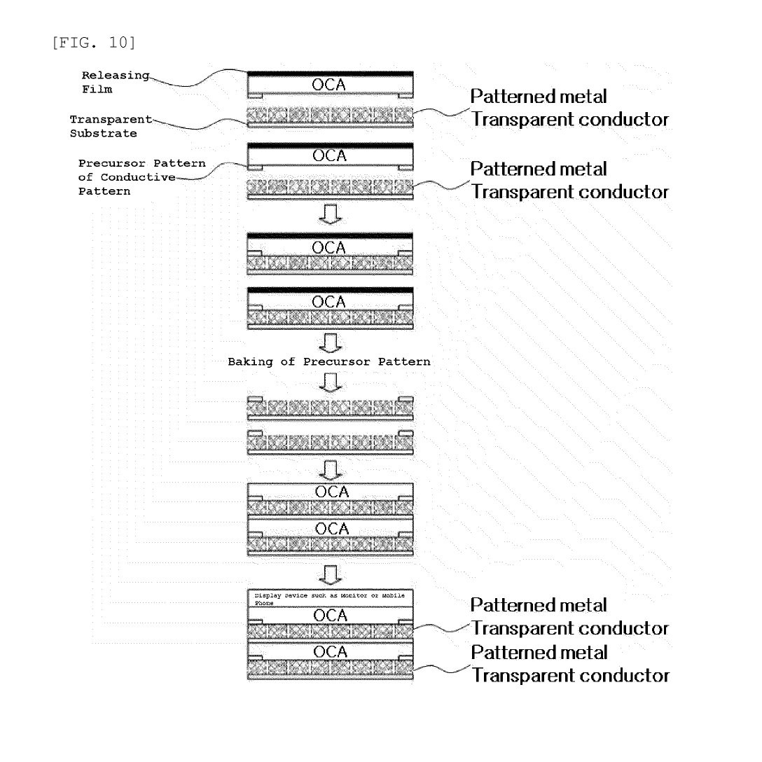

After the composition for forming a conductive pattern was applied on a polydimethylsiloxane (PDMS) blanket of a roller, the pattern of the composition for forming a conductive pattern was formed on the roller by contacting the blanket and a cliche on which a desired conductive pattern was formed. After that, by bringing this roller into contact with an adhesive film, a precursor pattern of a conductive pattern was formed on the adhesive film. The thickness of an adhesive layer of the adhesive film used at this time was 25 μm, and, after the adhesive film having a size of 2.5×12 cm² was prepared, the peel strength, evaluated in a 180° peel test method using a texture analyzer, was 3,000 N. The surface of the adhesive film on which the precursor pattern of a conductive pattern is provided was laminated on a PET substrate. Subsequently, the laminated substrate was baked for 30 minutes at 130° C., and the adhesive film was peeled from the PET substrate, and a conductive pattern was obtained on the PET substrate. An optical microphotograph of the conductive pattern obtained is shown in FIG. 3. At this time, the specific resistance of the conductive pattern material obtained was 20 μΩ·cm.

### Comparative Example 1

A composition for forming a conductive pattern was prepared by mixing 30 g of silver nanoparticles having an average particle size of 120 nm, 1.7 g of a silver salt of neodecanoic acid (Ag-neodecanoate), 0.6 g of a surfactant, and 73 g of terpineol (vapor pressure of 0.042 torr; surface tension of 33.2 mN/m; solubility constant of 9.80 (cal/cm³)^{1/2} at 25° C.) as a first solvent, and by filtering the result using a filter of 1 micrometer after stirring for 24 hours.

When the composition for forming a conductive pattern was applied on a polydimethylsiloxane (PDMS) blanket of a roller, even after waiting for 10 minutes or more, and then bringing the blanket into contact with a cliche on which a desired conductive pattern was formed by engraving, the ink-coated film was split into the embossed part of the cliche and the blanket, and the thickness thereof became small, and as a result, a favorable pattern was not formed on a substrate.

### Comparative Example 2

The composition for forming a conductive pattern was prepared by mixing 25 g of silver nanoparticles having an average particle size of 80 nm, 4 g of terpineol (vapor pressure of 0.042 torr; surface tension of 33.2 mN/m; solubility constant of 9.80 (cal/cm³)^{1/2} at 25° C.) and 36 g of propyl cellosolve (vapor pressure of 0.98 torr; surface tension of 26.3 mN/m; solubility constant of 10.87 (cal/cm³)^{1/2} at 25° C.) as a first solvent, and 33 g of ethanol (vapor pressure of 59.3 torr; surface tension of 22.1 mN/m; solubility constant of 12.98 (cal/cm³)^{1/2} at 25° C.) as a second solvent, and by filtering the result using a 1 micrometer filter after stirring for 24 hours.

When an attempt was made to apply the composition for forming a conductive pattern on a PDMS blanket of a roller, it was not uniformly applied and dewetted, therefore, application was impossible due to the aggregation of ink drops.

1. An adhesive substrate for forming a conductive pattern comprising:
an adhesive substrate; and
a precursor pattern of a conductive pattern provided on one side of the adhesive substrate.

2. The adhesive substrate for forming a conductive pattern of claim 1, wherein the precursor pattern of a conductive pattern is a pattern formed with materials prior to the baking of a conductive pattern, the materials exhibiting conductivity due to the baking.

3. The adhesive substrate for forming a conductive pattern of claim 1, wherein the precursor pattern of a conductive pattern includes a material that can exhibit conductivity when baked at a temperature of 150° C. or less.

4. The adhesive substrate for forming a conductive pattern of claim 1, wherein the conductive pattern includes a bezel electrode pattern of a touch screen, a metal electrode pattern for touch sensing, or includes both.

5. The adhesive substrate for forming a conductive pattern of claim 1, wherein the precursor pattern of a conductive pattern is formed using a composition that includes conductive particles and a solvent.

6. The adhesive substrate for forming a conductive pattern of claim 5, wherein a particle size of the conductive particles is 2 micrometers or less.

7. The adhesive substrate for forming a conductive pattern of claim 5, wherein the solvent includes a first solvent having a vapor pressure of 3 torr or less at 25° C. and a second solvent having a vapor pressure of greater than 3 torr at 25° C.

8. The adhesive substrate for forming a conductive pattern of claim 5, wherein the solvent includes a solvent having a solubility constant of 10 (cal/cm3)½ or more when presented in an amount of 80% by weight or more based on a total weight of the solvent.

9. The adhesive substrate for forming a conductive pattern of claim 5, wherein the precursor pattern of a conductive pattern further includes at least one of a surfactant and an organic metal.

10. The adhesive substrate for forming a conductive pattern of claim 1, wherein the precursor pattern of a conductive pattern is formed using a composition that includes metal particles, a first solvent having a vapor pressure of 3 torr or less at 25° C., a second solvent having a vapor pressure of greater than 3 torr at 25° C., and a salt of metal carboxylic acid.

11. The adhesive substrate for forming a conductive pattern of claim 10, wherein the precursor pattern of a conductive pattern does not include a polymer binder or a releasing agent.

12. An adhesive substrate for forming a conductive pattern comprising:
an adhesive substrate; and
a conductive pattern provided on one side of the adhesive substrate.

13. The adhesive substrate for forming a conductive pattern of claim 12, wherein the conductive pattern includes a bezel electrode pattern of a touch screen, a metal electrode pattern for touch sensing, or includes both.

14. The adhesive substrate for forming a conductive pattern of claim 12, wherein the conductive pattern is formed using a composition that includes a material that can exhibit conductivity when baked at a temperature of 150° C. or less.

15. The adhesive substrate for forming a conductive pattern of claim 12, wherein the conductive pattern is formed using a composition that includes metal particles, a solvent that includes a first solvent having a vapor pressure of 3 torr or less at 25° C., a second solvent having a vapor pressure of greater than 3 torr at 25° C., and a salt of metal carboxylic acid.

16. The adhesive substrate for forming a conductive pattern of claim 15, wherein the solvent includes a solvent having a solubility constant of 10 (cal/cm3)½ or more when presented in an amount of 80% by weight or more based on a total weight of the solvent.

17. The adhesive substrate for forming a conductive pattern of claim 15, wherein the composition does not include a polymer binder or a releasing agent.

18. The adhesive substrate for forming a conductive pattern of claim 12, wherein the conductive pattern further includes at least one of a surfactant and an organic metal.

19. A method for preparing the adhesive substrate for forming a conductive pattern of claim 1, comprising the step of:
forming a precursor pattern of a conductive pattern on an adhesive substrate.

20. The method for preparing the adhesive substrate for forming a conductive pattern of claim 19, wherein the step of forming the precursor pattern of a conductive pattern on the adhesive substrate is performed using a reverse offset printing method, a Gravure offset printing method, or an inkjet printing method.

21. A method for preparing the adhesive substrate for forming a conductive pattern of claim 12, comprising the steps of:
forming a precursor pattern of a conductive pattern on an adhesive substrate; and
forming a conductive pattern by baking the precursor pattern of a conductive pattern.

22. The method for preparing the adhesive substrate for forming a conductive pattern of claim 21, wherein the step of forming the precursor pattern of a conductive pattern on the adhesive substrate is performed using a reverse offset printing method, a Gravure offset printing method, or an inkjet printing method.

23. A method for preparing a conductive pattern, comprising the steps of:
preparing the adhesive substrate for forming a conductive pattern of claim 1, which includes an adhesive substrate and a precursor pattern of a conductive pattern provided on one side of the adhesive substrate;
laminating the surface, on which the precursor pattern is provided, of the adhesive substrate for forming a conductive pattern on an additional substrate; and
forming a conductive pattern by baking the precursor pattern before or after laminating the additional substrate and the adhesive substrate for forming a conductive pattern.

24. The method for preparing a conductive pattern of claim 23, further comprising the step of:
removing the adhesive substrate after laminating the additional substrate and the adhesive substrate for forming a conductive pattern.

25. A method for preparing a conductive pattern, comprising the steps of:
preparing the adhesive substrate for forming a conductive pattern of claim 12, which includes an adhesive substrate and a conductive pattern provided on one side of the adhesive substrate; and
laminating the surface, on which the conductive pattern is provided, of the adhesive substrate for forming a conductive pattern on an additional substrate.

26. The method for preparing a conductive pattern of claim 25, further comprising the step of:
removing the adhesive substrate after laminating the additional substrate and the adhesive substrate for forming a conductive pattern.

27. A conductive pattern formed using the method for preparing a conductive pattern of claim 23.

28. The conductive pattern of claim 27, wherein a specific resistance is 100 μΩ·cm or less.

29. An electronic device including the conductive pattern of claim 27.
